(19) United States
(12) Patent Application Publication
(10) Pub. No.: US 2013/0171921 A1
(43) Pub. Date: Jul. 4, 2013

(54) DISPLAY DEVICE

(71) Applicant: SANYO ELECTRIC CO., LTD., Osaka (JP)

(72) Inventor: Masaya NAKAMICHI, Osaka (JP)

(73) Assignee: SANYO ELECTRIC CO., LTD., Osaka (JP)

(21) Appl. No.: 13/780,433

(22) Filed: Feb. 28, 2013

Related U.S. Application Data
(63) Continuation-in-part of application No. PCT/JP2011/069378, filed on Aug. 29, 2011.
Application No. PCT/JP2011/069378 is a continuation-in-part of application No. PCT/JP2011/069380, filed on Aug. 29, 2011.

(30) Foreign Application Priority Data
Aug. 30, 2010 (JP) 2010-192572
Aug. 30, 2010 (JP) 2010-192574
Aug. 30, 2010 (JP) 2010-192575

(51) Int. Cl. H05K 5/02

(52) U.S. Cl. CPC H05K 5/0213
USPC 454/184

(57) ABSTRACT

The instant application describes a display device including a display panel; a cabinet which accommodates the display panel; an aeration part provided inside the cabinet, the aeration part which communicates between the outside the inside of the cabinet; a fan which leads air to the inside or to the outside of the cabinet via the aeration part; a filter arranged in the aeration part, and an alerting part arranged in the back side of the display panel, and informs a clog up of the filter.

### CROSS-REFERENCE TO RELATED APPLICATIONS

This application is a continuation-in-part of Patent Cooperation Treaty Patent Application Number PCT/JP2011/069378 filed on Aug. 29, 2011, which claims priority from Japanese Patent Application Number 2010-192572 filed on Aug. 30, 2010, and of Patent Cooperation Treaty Patent Application Number PCT/JP2011/069380 filed on Aug. 29, 2011, which claims priority from Japanese Patent Application Number 2010-192575 filed on Aug. 30, 2010 and Japanese Patent Application Number 2010-192574 filed on Aug. 30, 2010, all of which are hereby incorporated by reference herein in their entirety.

### TECHNICAL FIELD

The instant application relates to a display device comprising a display panel.

### BACKGROUND

Conventionally, most of the display device was designed for indoor use. Thus, it was not assumed that the screen of a display panel is heated by the sunlight entering from an image display window.

However, nowadays, it is desired to install a display device in the outdoors or install a display device inside a machine installed outdoors such as a vending machine. However, when a conventional display device is used in such case, since temperature of the screen of the display panel rises by sunlight, the display panel may not operate properly.

In order to solve this problem, one idea is to provide an inlet for inhaling an outdoor air to the cabinet and an outlet for exhausting air inside the cabinet to the outdoor, and forming a channel which communicates the inlet and the outlet. Further, a fan for blowing air inside the channel from the inlet to the outlet, and a filter for capturing dust included in the air inhaled from the inlet are provided.

In this type of display device, dust may accumulate in the filter during the operation of the display device, and as a result, the filter may clog up with dust. In such case, the filter should be replaced, however, when the replacement of the filter is put off, the temperature of the display panel may rise excessively and this may cause an improper operation of the panel. However, since it is difficult to recognize the clog up of the filter, the filter may not be replaced even when the time for replacement has elapsed.

In order to solve this problem, one idea is to exchange a filter from the opening end side of the inlet. On the other hand, it is necessary to provide a duct in this opening end in order to prevent the water intrusion from this opening end. However, in this structure, it is difficult to exchange the filter from the opening end side of the inlet.

### SUMMARY

In one general aspect, the instant application describes a display device including a display panel; a cabinet which accommodates the display panel; an aeration part provided inside the cabinet, the aeration part which communicates between the outside the inside of the cabinet; a fan which leads air to the inside or to the outside of the cabinet via the aeration part; a filter arranged in the aeration part, and an alerting part arranged in the back side of the display panel, and informs a clog up of the filter.

In another general aspect, the instant application describes a display device including a display panel; a cabinet which accommodates the display panel; an aeration part arranged in the cabinet, which communicates the outside and the inside of the cabinet, the aeration part facing its opening end to the lateral side and having an insertion window in the back side; a fan which leads air to the inside or outside of the cabinet via the aeration part, and a filter which is inserted from the insertion window and attached removable to the aeration part.

### BRIEF DESCRIPTION OF THE DRAWINGS

The figures depict one or more implementations in accord with the present teachings, by way of example only, not by way of limitations. In the figures, like reference numerals refer to the same or similar elements.

FIG. 1 is a perspective view of an exemplary display device of an instant application, when viewed from the front side.

FIG. 2 is a perspective view of the display device when viewed from the rear side.

FIG. 3 is a rear view of the display device.

FIG. 4 is an exploded perspective view of the display device, when viewed from the front side.

FIG. 5 is an exploded perspective view of the display device, when viewed from the rear side.

FIG. 6 is a sectional view of the display device along the A-A line in FIG. 3.

FIG. 7 is an enlarged view of the area B shown in FIG. 6.

FIG. 8 is an enlarged view of the area C shown in FIG. 6.

FIG. 9 is a sectional view of the display device along the D-D line in FIG. 3.

FIG. 10 is an enlarged view of the area E shown in FIG. 9.

FIG. 11 is an enlarged view of the area F shown in FIG. 9.

FIG. 12 is a perspective diagram view of the second air flow generating unit 62 of equipped in the display device.

FIG. 13 is an enlarged view of the second air flow generating unit 62.

FIG. 14 is a bottom perspective view of the display device.

FIG. 15 is an exploded perspective view of the display device, when viewed from the bottom side.

FIG. 16 is perspective view of a front cabinet of the display device, when viewed from the upper rear side.

FIG. 17 is perspective view of a front cabinet, when viewed from the bottom rear side.

FIG. 18 is an enlarged view of a cover portion of the display device.

FIG. 19 is a sectional view of a modified drainage structure of the display device.

FIG. 20 is an exploded perspective view of the inlet equipped in the display device.

FIG. 21 is an exploded perspective view of the inserting unit and an inlet side filters of the display device.

FIG. 22 is a perspective view of the inserting unit when it is fixed to the inlet.

FIG. 23 is a block diagram showing a composition for informing a clog up of the filter in the display device.

FIG. 24 is an enlarged view of the area G shown in FIG. 2.

### DETAILED DESCRIPTION

In the following detailed description, numerous specific details are set forth by way of examples in order to provide a thorough understanding of the relevant teachings. However, it should be apparent to those skilled in the art that the present teachings may be practiced without exemplary details. In other instances, well known methods, procedures, components, and/or circuitry have been described at a relatively high-level, without detail, in order to avoid unnecessarily obscuring aspects of the present concepts. In exchange for the present disclosure herein, the Applicants desire all patent rights described in the claims. Therefore, the patent rights are not intended to be limited or restricted by the following detailed description and accompanying figures.

### 1. Structure of Display Device

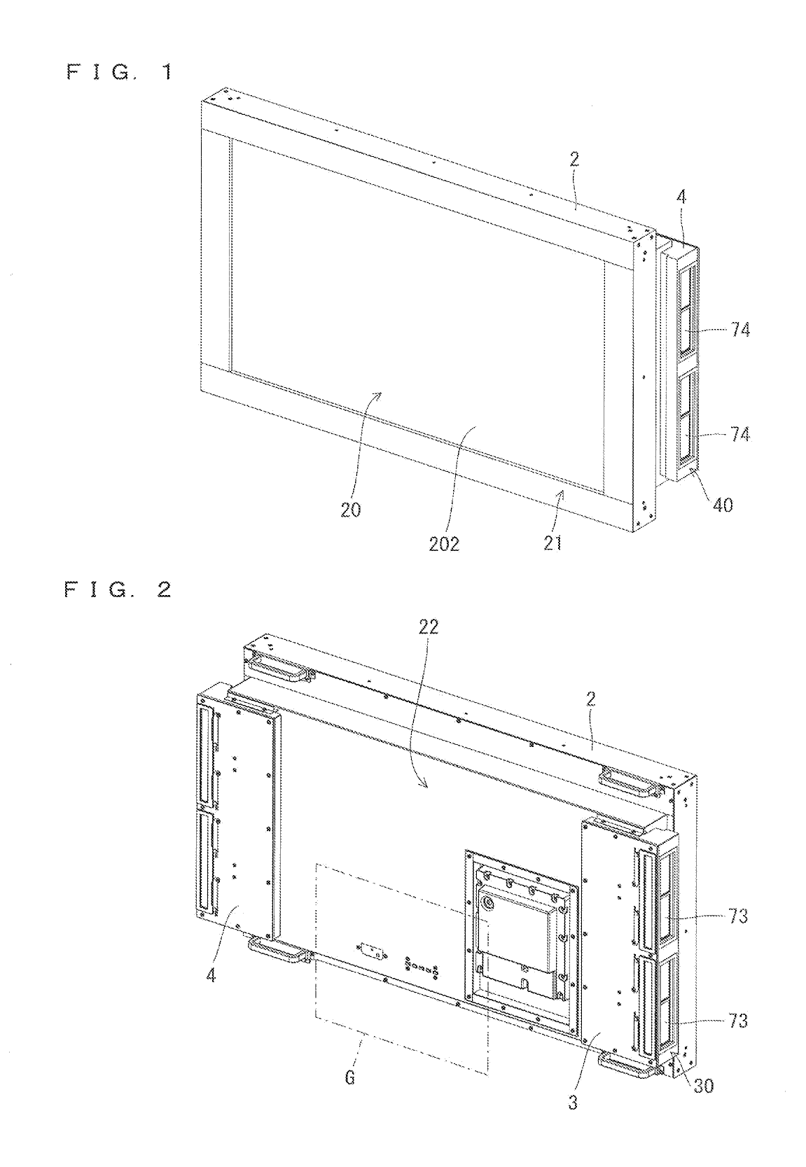

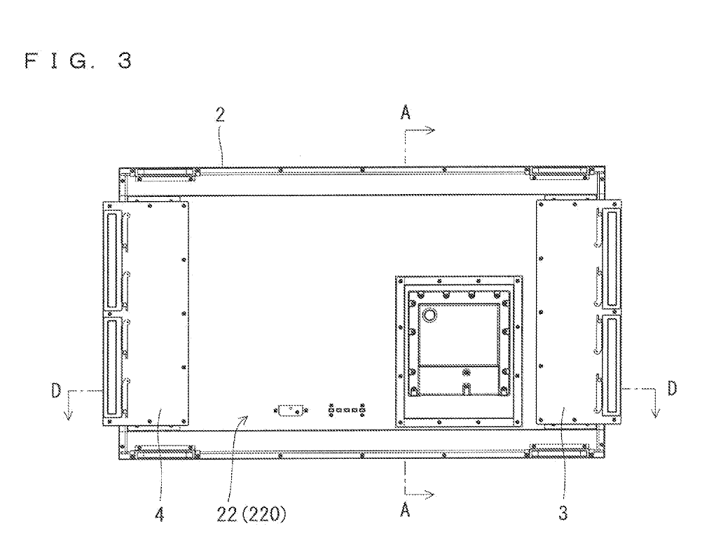

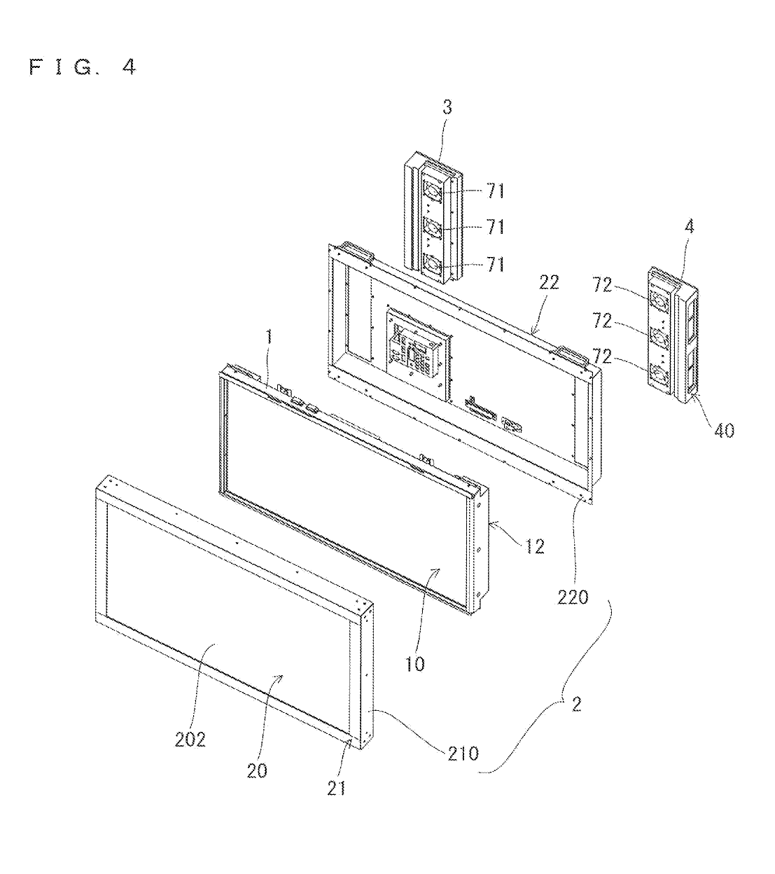

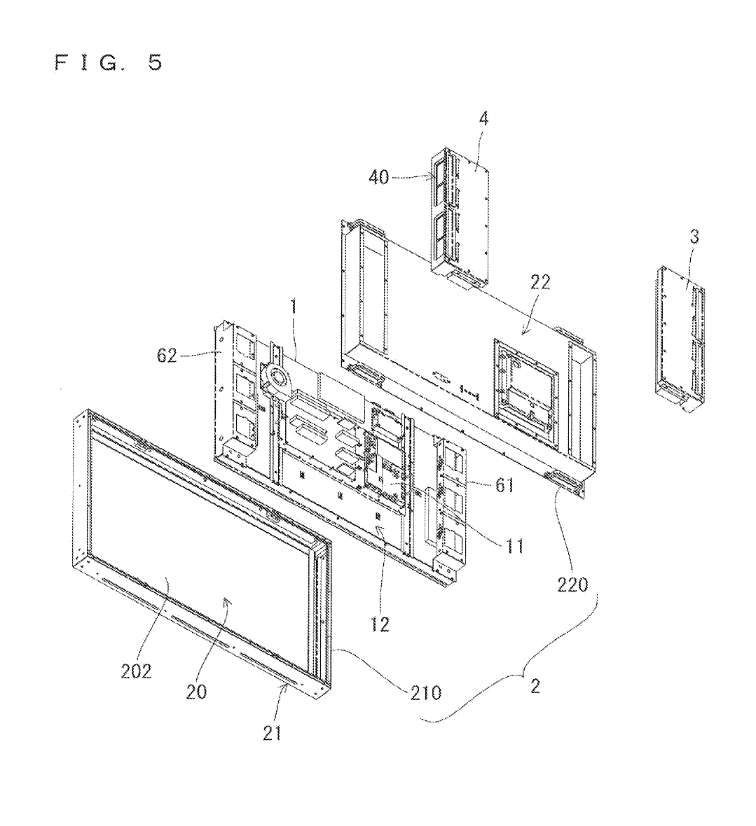

FIGS. 1 and 2 are perspective views of an exemplified display device of an instant application, when viewed from the front side and back side respectively. FIG. 3 is a rear view of this display device. FIGS. 4 and 5 are exploded perspective views of this display device when viewed from the front side and back side respectively. As shown in FIGS. 1 to 3, this display device has a cabinet (2). As shown in FIGS. 4 and 5, the cabinet (2) is constituted by jointing a front cabinet (210) which is a front wall (21) of the cabinet (2), and a back cabinet (220) which is a back wall (22) of the cabinet (2). Inside the cabinet (2), an LCD panel (1) and a circuit board (11) for controlling the panel (1) are accommodated. The circuit board (11) is installed in the back surface (12) of the LCD panel (1). Further, the display device may be installed inside a machine such as a vending machine, or may be used independently instead of being installed inside the particular machine.

Here, in the front wall (21) of the cabinet (2), an image display window (20) which enables the screen (10) of the LCD panel (1) viewable from the outside. The window (20) is covered by a glass board (202). The glass board (202) is provided with an electric capacity-type touch panel.

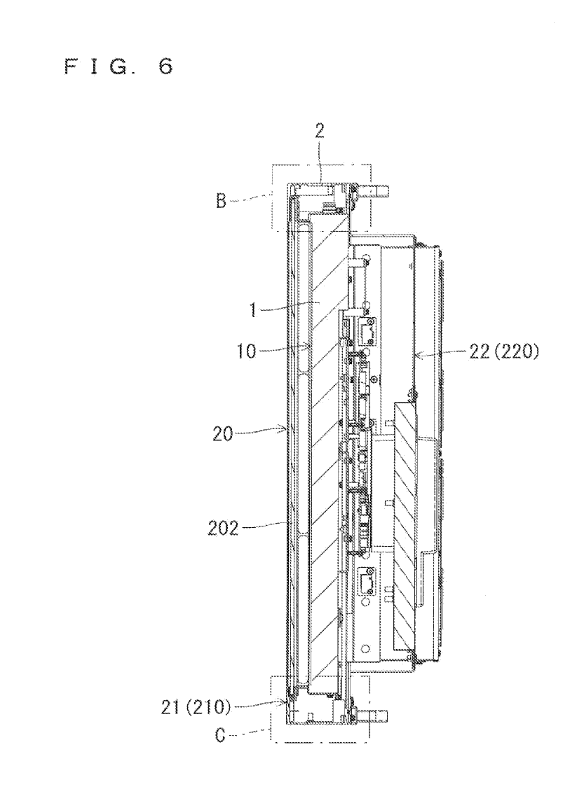

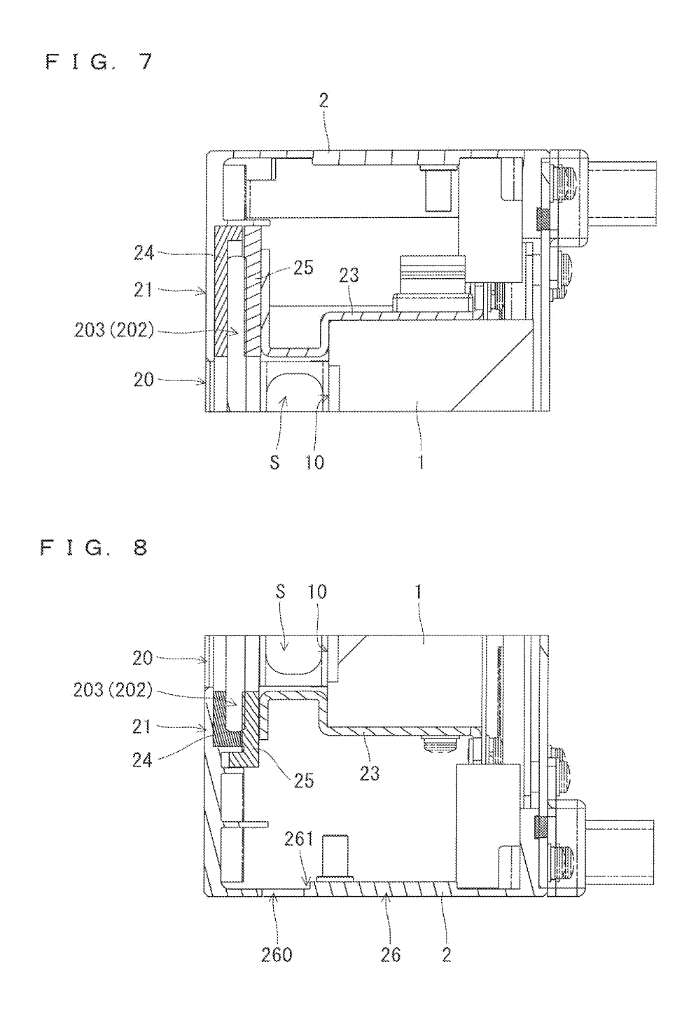

FIG. 6 is a sectional view of the display device along the A-A line in FIG. 3. FIG. 7 is an enlarged view of the area B shown in FIG. 6. FIG. 8 is an enlarged view of the area C shown in FIG. 6. As shown in FIGS. 7 and 8, the glass board (202) has a dimension larger than the image display window (20). The outer edge part (203) of the glass board (202) overlaps the front wall (21) of a cabinet (2) in the inner side. Inside the cabinet (2), a metal fitting (23), which presses the glass board (202) toward the front wall (21), is provided. By a pressing force of the metal fitting (23), the glass board (202) is jointed with the inner side of the front wall (21). The LCD panel (1) is installed in the position so that a space is formed between the screen (10) of this panel (1) and the glass board (202).

As shown in FIGS. 7 and 8, between the jointing surfaces of the front wall (21) and the glass board (202), a sealing component (24) surrounding the image display window (20) is intervened. By this, intrusion of water from between the jointing surfaces is prevented. Between the glass board (202) and the metal fitting (23), a buffer component (25) is intervened.

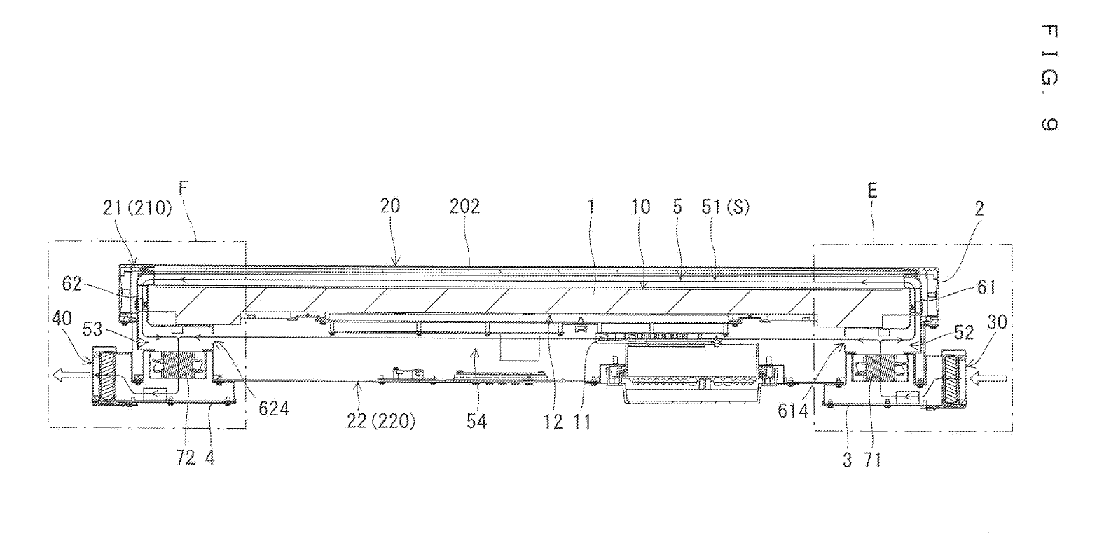

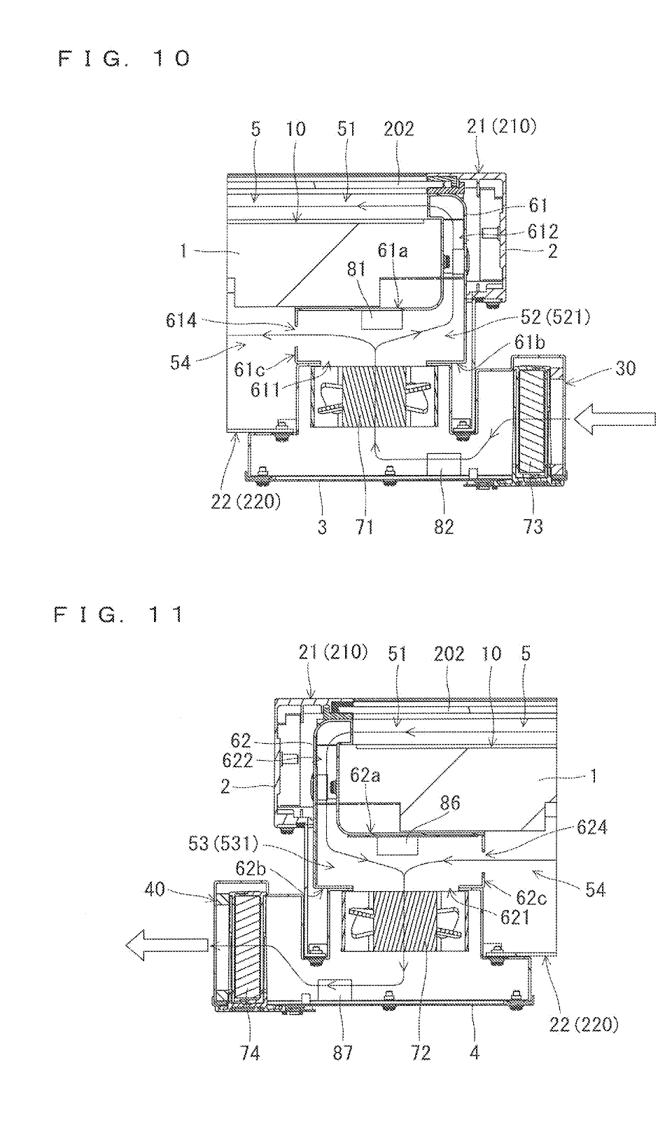

FIG. 9 is a sectional view of the display device along the D-D line in FIG. 3. FIGS. 10 and 11 are enlarged views of the areas E and F shown in FIG. 9 respectively. As shown in FIGS. 9 to 11 (see FIGS. 1 to 5 also), in the backwall (22) of the cabinet (2), the inlet (3) and the outlet (4) for communicating the inside and the outside of the cabinet (2) is provided. The inlet (3) is arranged so that its opening end (30) faces toward the right-hand side. The outlet (4) is arranged so that its opening end (40) faces toward the left-hand side. The inlet (3) functions as an aeration part which passes air towards the inside of a cabinet (2) from the outside. The outlet (4) functions as an aeration part which passes air towards the outside of the cabinet (2) from the inside. In this example, both inlet (3) and the outlet (4) have a geometry which is elongated in the perpendicular direction.

As shown in FIG. 9, a channel (5) which is prolonged from the inlet (3) and reaching the outlet (4) is formed inside the cabinet (2). This channel (5) includes a space S between the screen (10) of the LCD panel (1), and the glass board (202). The channel (5) comprises a first channel (51), an inlet side channel (52), and an outlet side channel (53). The first channel (51) passes along the screen (10) of the LCD panel (1) in the horizontal direction. The inlet side channel (52) is prolonged from the inlet (3), passes the right-hand side of the LCD panel (1), and then reaches the first channel part (51). The outlet channel (53) is prolonged from the outlet (4), passes the left-hand side the LCD panel (1), and then reaches the first channel (51).

Here, the first channel (51) is formed by the screen (10) and the glass board (202). The channels (52) and (53) are formed by air flow generating units (61) and (62) respectively, as shown in FIGS. 5 and 9.

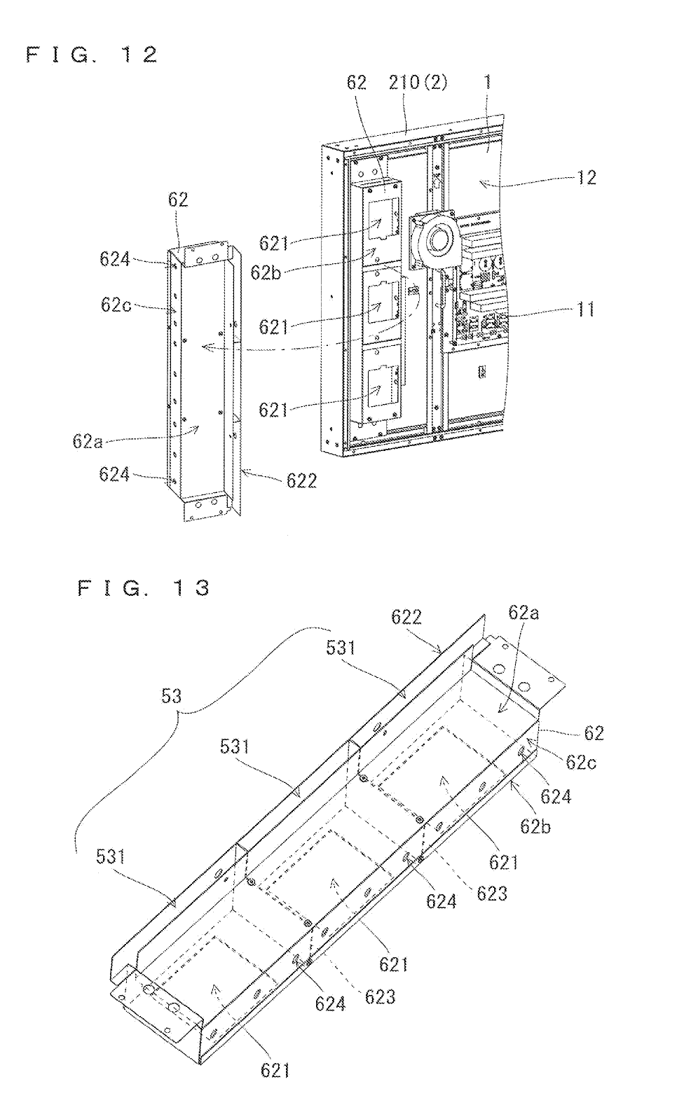

FIG. 12 is a perspective view showing the second air flow generating unit (62), and FIG. 13 is an enlarged view of the unit (62). As shown in FIGS. 12 and 13 (see FIG. 11 also), in the back wall (62b) of the unit (62), the openings (621) are formed in three places, in the upper row, the middle row, and in the lower row. In the front wall (62a) of the unit (62), a slit-like path (622) prolonged in the vertical direction is provided. Each of the openings (621) and the passage (622) is communicated mutually inside the unit (62).

As shown in FIG. 13, inside the second air flow generating unit (62), two partition components (623) (623) extending from the back wall (62b) to the front wall (62a) and further to the path (622) are provided. Here, each partition component (623) is a tabular component which extends in the horizontal direction when the display device is assembled. Thereby, space inside the unit (62), (namely, the outlet side channel (53)) is divided into three spaces (531) (531). For each of the spaces (531), one opening (621) is provided, and the space (531) is communicated with the path (622) via the corresponding opening (621). Thereby, the outlet side channels (53) are divided into a plurality of spaces (531)-(531), each of the spaces communicates from the outlet (4) to the first channel (51) by the partition components (623) (623).

The first air flow generating unit (61) has the same structure as the second air flow generating unit (62). Referring to FIG. 10, in a back wall (61b) of the unit (61), openings (611) are formed in three places. In the front wall (61a) of the unit (61), a slit like path (612) prolonged in the vertical direction is provided. The spaces inside the unit (61) (namely, the inlet side channel (52)) is divided into three space (521) (521) by partition component. For each of the spaces (521), one opening (611) is provided, and the space (521) communicates with a path (612) via the opening (611). Thereby, the inlet side channel (52) is divided into a plurality of spaces (521) (521), each of the spaces communicates with from the inlet (3) to the first channel (51), by the partition component.

Further, as shown in FIGS. 12 and 13, in the side wall (62c) of the second air flow generating unit (62), nine penetration holes (624) (624) are arranged in the perpendicular direction. Corresponding to each of the three spaces (531) (531) in the unit (62), three penetration holes (624) are provided. Each of the holes (624) is for communicating the space in the back surface (12) side of the LCD panel (1) and the space in the unit (62) (i.e. outlet side channel (53)) when the display device is assembled, as shown in FIG. 11.

Referring to FIG. 10, in the side wall (61c) of the first air flow generating unit (61), nine penetration holes (614) (614) are formed, as well as in the second air flow generating unit (62). Therefore, the space in the back surface (12) side of the LCD panel (1) and the space in the unit (61) (i.e., inlet side channel (52)) are communicated mutually via the penetration hole (614).

Further, in inside the cabinet (2), a second channel part (54) which passes the back surface (12) side of the LCD panel (1) and prolongs from the inlet side channel (52) to the outlet side channel (53) is formed, as shown in FIG. 9. Thereby, a portion of the channel (5) is constituted by this second channel part (54).

As shown in FIG. 4, in the inlet (3), three fans (71) (71) are arranged facing forward. As shown in FIG. 10, each of the fans (71) is arranged for each of the spaces (521) in the inlet side channel (52), and is arranged so that the fan (71) can blow air into this space (521). Therefore, by driving each of the fans (71), air in the inlet (3) moves to the corresponding space (521) for respective fans (71) as shown by solid line arrow in FIG. 10. Then, this air flows inside the space (521) to the horizontal direction, without being mixed with the air inside the space (521), and flows into the first channel (51) and second channel (54). Thereby, the air outside of the cabinet is inhaled inside from the opening end (30) of the inlet (3).

As shown in FIG. 4, in inside the outlet (4), three fans (72) (72) are arranged facing forward. As shown in FIG. 11, each of the fans (72) is provided for each of the spaces (531) in the outlet side channel (53), and is arranged so that the air inside the space (531) can be exhausted outside. Therefore, by driving each of the fans (72), air in the first channel (51) and the second channel (54) flows into its corresponding space (531), as shown by solid line arrow in FIG. 11. Then, the air flows through the space (531) horizontally and reaches the outlet (4). Thereby, the air inside the cabinet is exhausted from the opening end (40) of the outlet (4).

Therefore, by driving the fans (71) and (72), as shown by a solid line arrow in FIG. 9, in each of the first channel (51) and the second channel (54), the air flow moving horizontally from the inlet side to the outlet side are generated.

As shown in FIG. 2 and FIG. 10, in the inlet (3), a pair of the filters (73) (73) are formed in the position near the opening end (30). As shown in FIG. 1 and FIG. 11, in the outlet (4), a pair of the filters (74) (74) are formed in the position near the opening end (40). Here, the inlet side filter (73) has high filtering function (high dust collecting performance) compared to the outlet side filter (74). The outlet side filter (74) is consisted by meshes, and the inlet side filter (73) is consisted by piling up the mesh and a filter finer than the mesh (see FIG. 21).

In the above-mentioned display device, cool air outside the cabinet is inhaled inside the cabinet from the inlet (3), by the fans (71) and (72), and this air flows to the outlet (4) along the channel (5). At this time, the air flowing inside the first channel (51) absorbs the heat on the screen (10) of the LCD panel (1), and the air flowing inside the second channel (54) absorbs the heat on the circuit board (11). The air warmed in the first channel (51) and the second channel (54) is exhausted outside the cabinet from the outlet (4).

Here, in the above-mentioned display device, the air from each of the fans (71) in the inlet (3) flows horizontally inside its corresponding space (521), without being mixed with the air which flows inside the other spaces (521), and eventually flows into the first channel (51) and the second channel (54). Thereby, air sent out from the three fans (71) (71) do not collide each other and do not generate turbulent flow nor whirlpool. Thus, air can flow uniformly along the screen (10) of the LCD panel (1) (i.e., inside the first channel (51)), and can flow uniformly along the back surface (12) of the panel (1) (i.e. inside the second channel (54)).

Therefore, according to the above-mentioned display device, the whole screen (10) of the LCD panel (1) and the circuit board (11) is cooled efficiently by the air inhaled from the inlet (3). Therefore, even when the screen (10) of the LCD panel (1) is heated by the sunlight entering from the image display window (20), and the circuit board (11) is heated by its activation, it can prevent temperature of the screen (10) of the panel (1) and the circuit board (11) from rising, and can maintain the proper operation of the panel (1) and the board (11). Further, since air can flow uniformly inside the first channel (51), the sensitivity unevenness in the touch panel attached on the glass board (202) is prevented.

Further, even when the temperature outside the display device is low, it can prevent from occurring dew condensation on the inner side of a glass board (202), because cool air is sent inside the first channel (51) and the temperature difference between the glass board (202) and the outside air can be made small. Further, even when the dew condensation has occurred on the inner side of the glass board (202) or the screen (10) of the LCD panel (1), the condensed water-drop is blown by the air flowing on the screen (10) of the panel (1). Therefore, it can prevent water-drop from attaching on the screen (10) of the panel (1) and the glass board (202), and thus, the screen (10) of the LCD panel (1) is maintained viewable.

In the above-mentioned display device, when the fans (71) and (72) drive, the large amount of air outside the cabinet flows inside the cabinet via the inlet (3). Here, the inlet side filter (73) has high filtering function (dust collecting performance) compared with the outlet side filter (74). Therefore, even when a large amount of air is inhaled from the inlet (3), most of the dust in this air is captured by the inlet side filter (73). Thus, the air containing few dust is introduced inside the cabinet, and can prevent the malfunction of the LCD panel (1) caused by the dust.

In the above-mentioned display device, in the outlet (4), a pair of the outlet side filter (74) (74) is formed. Thus, even when the outside air flows inside the cabinet (2) through the outlet (4) while the fans (71) and (72) are not driven, dust inside this air is captured by the outlet side filters (74) (74). Therefore, invasion of dust inside the cabinet is prevented, and, malfunction of the LCD panel (1) and the circuit board (11) caused by the dust are prevented.

### 2. Structure of Water Drainage and the Structure for Allowing the Cleaning Inside the Cabinet

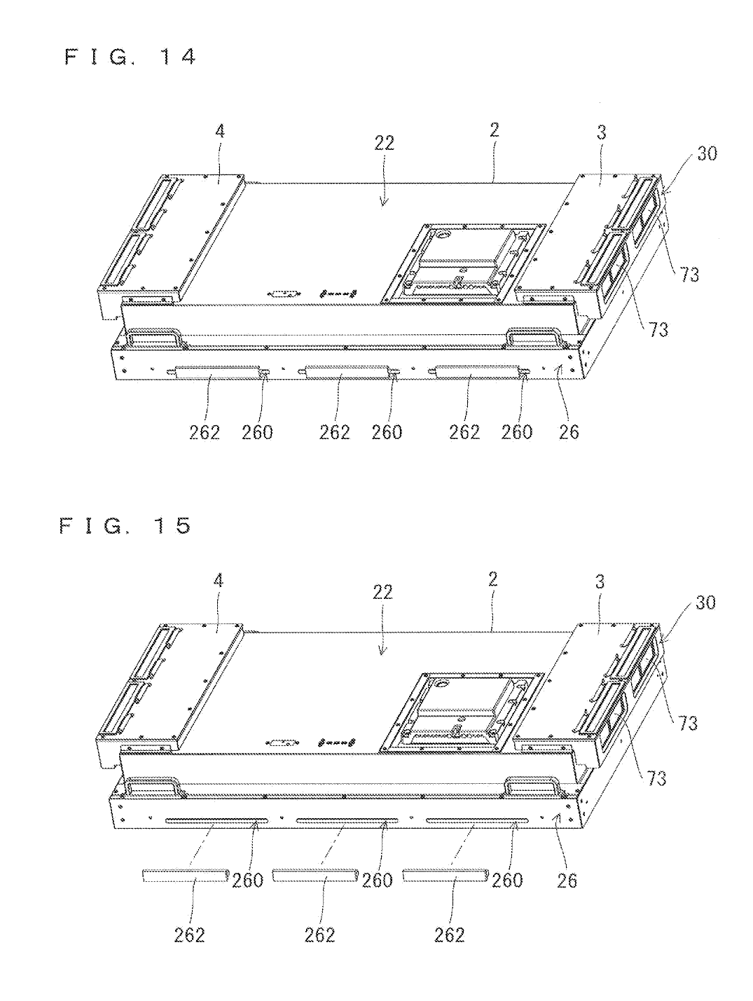

FIGS. 14 and 15 are the perspective view and the exploded perspective view of the above-mentioned display device respectively, when viewed from the bottom side. As shown in FIG. 15, in the bottom wall (26) of the cabinet (2), three openings (260) (260) penetrating this wall (26) from the inner surface to the outer surface are formed. Here, each of the openings (260) is formed prolonged in the transverse direction, and these three openings (260) are located in a line.

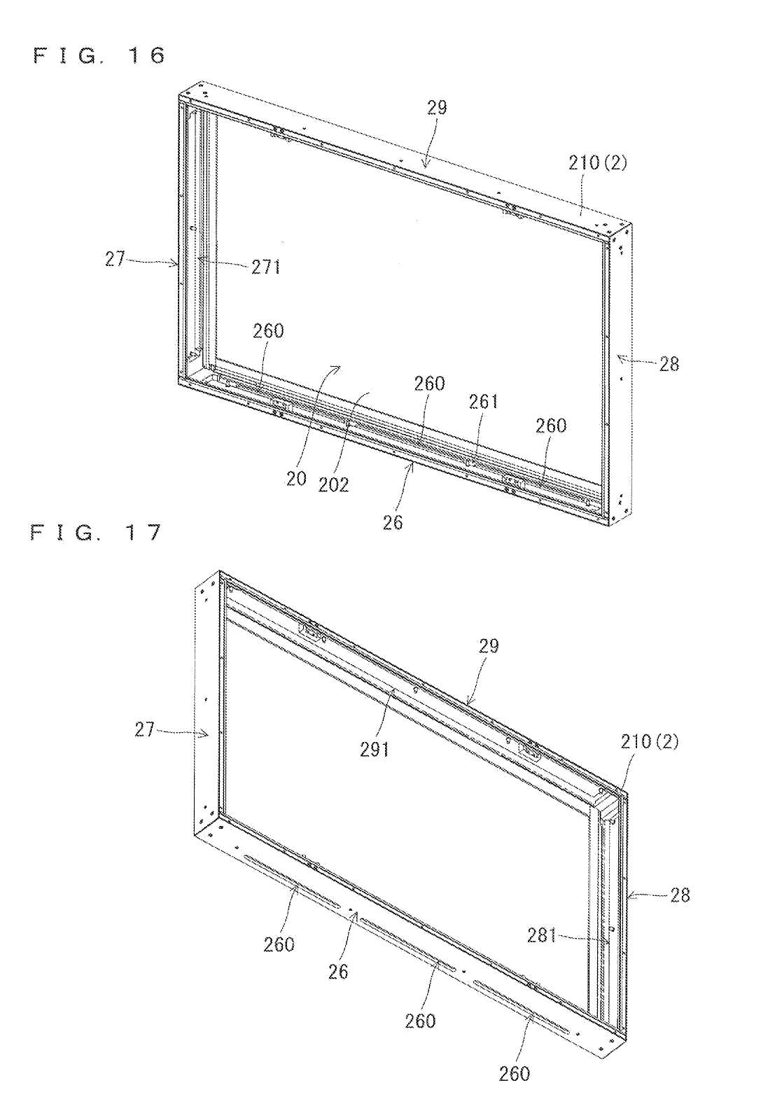

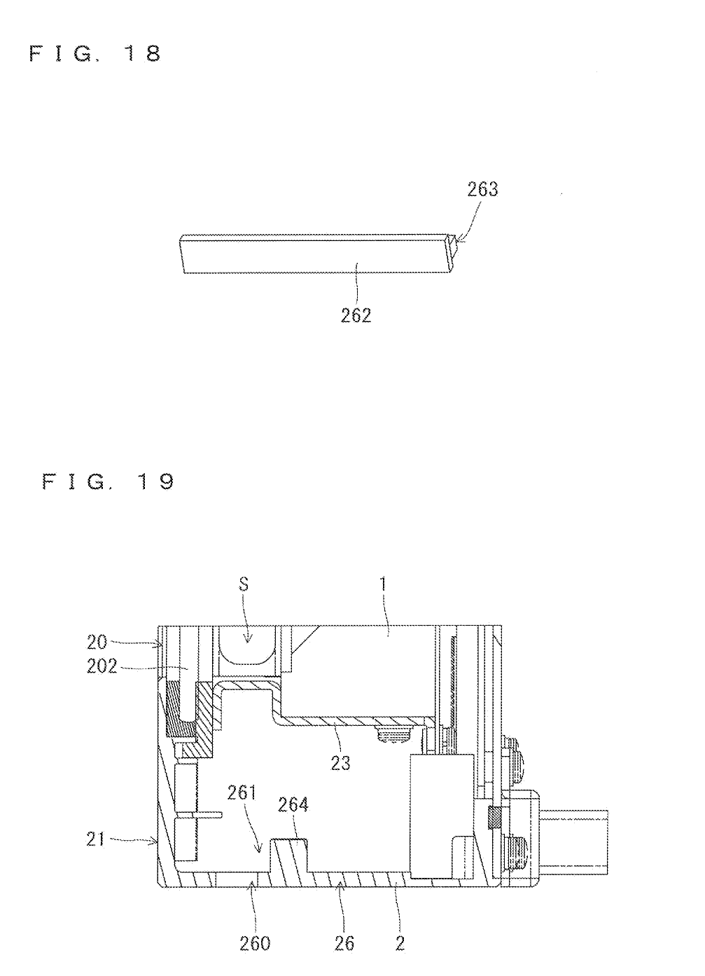

FIG. 16 and FIG. 17 are perspective views of the front cabinet (210) when viewed from the upper rear side and lower rear side, respectively. As shown in FIG. 16 (see FIG. 8 also), in the bottom wall (26) of the cabinet (2), a first groove (261) for guiding water to the openings (260) (260) is provided. Further, as shown in FIGS. 16 and 17, in side walls (27) and (28), which are respectively provided on the left and right side of the cabinet (2), second grooves (271) and (281) for guiding water to the bottom wall (26) in order to emit the water outside are formed respectively. Further, as shown in FIG. 17, in the upper wall (29) of the cabinet (2), a third groove (291) for leading water to the side wall (27) is formed in order to emit the water outside.

As shown in FIG. 14 and FIG. 15, in the bottom wall (26) of the cabinet (2), a cover component (262) covering the center area of each of the openings (260) is attached removable. As shown in FIG. 18, in the cover component (262), a fitting portion (263) which fits to the opening (260) is formed. By fitting this portion (263) to the opening (260), the cover component (262) is attached to the bottom wall (26) of the cabinet (2) as shown in FIG. 14.

In the above-mentioned display device, as shown in FIG. 8 and FIG. 15, by removing the cover component (262) from the bottom wall (26) of the cabinet (2), and by inserting a stick-like cleaning implement to the inside of the cabinet from each opening (260), dust adhering the screen (10) of the LCD panel (1) can be removed. As such, the display device has the structure for enabling cleaning inside the cabinet (screen (10) of the panel (1)). Further, in this display device, in the holding metal fitting (23), an opening is formed in order to insert the cleaning implement for cleaning the screen (10).

At the times other than the cleaning, as shown in FIG. 14, the cover component (262) is attached to the bottom wall (26) of the cabinet (2). Thereby, invasion of dust from the opening (260) is inhibited. Further, when the cover component (262) is attached to the bottom wall (26), while the center area of the opening (260) is covered by the cover component (262), the edge areas of the opening (260) are still exposed. Therefore, these exposed areas can function as water drain. Thus, for example, even when the seal component (24) of the display device installed outdoors deteriorates and water intrudes inside the cabinet, the water move down to the bottom wall (26) by gravity, and can emit outside from these exposed areas (drain) of the opening. Further, even when dew condensation occurs in the cabinet (2), dewed water moves down to the bottom wall (26) by gravity, and is emitted outside from the exposed area of the opening. Thereby, water inside the cabinet is emitted outside. Such drainage structure is realized because this display device has the structure in which air flows horizontally inside the cabinet (2).

In the above-mentioned display device, since the second groove (271) (281) are formed in the inner side of the side walls (27) and (28), and the third groove (291) is formed in the inner side of the upper wall (29), the water generated inside the cabinet is guided efficiently to the bottom wall (26). Further, since the first groove (261) is formed in the inner surface of the bottom wall (26), water on the bottom wall (26) can move to the exposed area (water drain) in the opening (260), and water is emitted efficiently from the exposed area.

FIG. 19 is a sectional view of a modified drainage structure of the above-mentioned display device. As shown in FIG. 19, a protuberance portion (264) may be formed in the inner surface of the bottom wall (26) stretching toward the horizontal direction along this inner surface. Then, a first groove (261) may be formed between this protuberance portion (264) and the front wall (21) of the cabinet (2).

In the above-mentioned display device, besides the opening (260) which functions as water drain, the additional opening may be provided in the side walls (27) (28) or the upper surface (29) of the cabinet (2) for inserting a stick-like cleaning implement inside the cabinet, and a cover component for covering this opening may be attached removable.

### 3. Structure for Exchanging a Filter

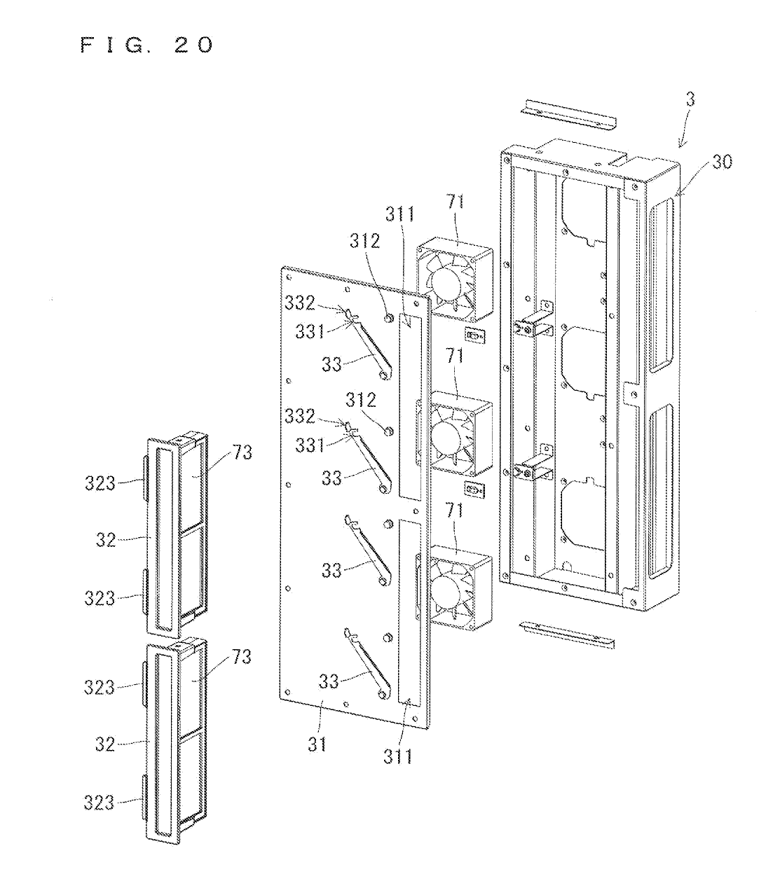

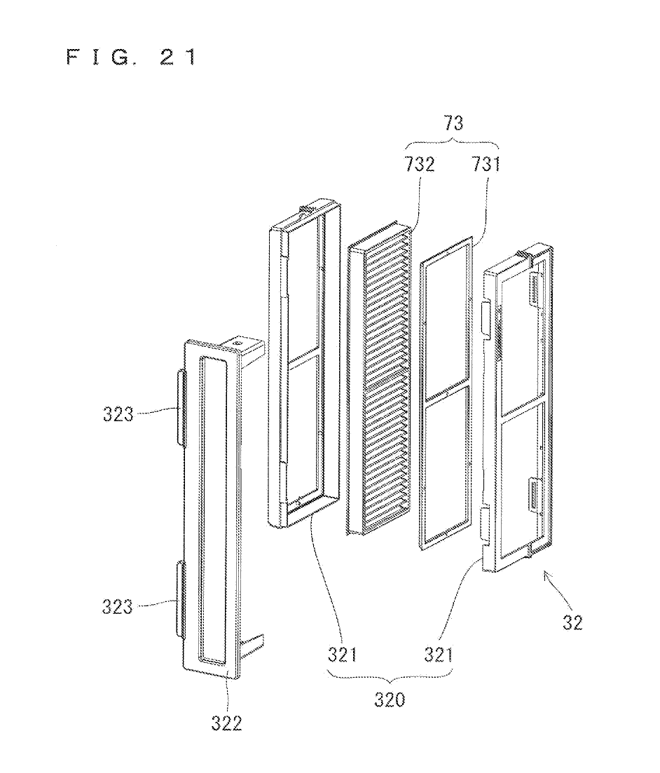

FIG. 20 is an exploded perspective view of the inlet (3). As shown in FIG. 20, in the back portion (31) of the inlet (3), a pair of insertion windows (311) (311) for inserting a pair of inlet side filters (73) (73) into the inlet (3) are provided. The display device has an inserting unit (32) which is removable with each of the insertion windows (311), and the inlet side filter (73) is attached to this inserting unit (32).

FIG. 21 is an exploded perspective view of the inserting unit (32) and the inlet sides filter (73). As shown in FIG. 21, each of the inserting units (32) consists of an accommodation case (320) constituted by jointing half cases (321) (321), and a support medium (322) which supports this accommodation case (320). Each of the inlet side filters (73) is consisted by a mesh (731) and a filter material (732) which is finer than the mesh (731). In the accommodation case (320) of the inserting unit (32), the mesh (731) and the filter material (732) are accommodated in a state they are piled up.

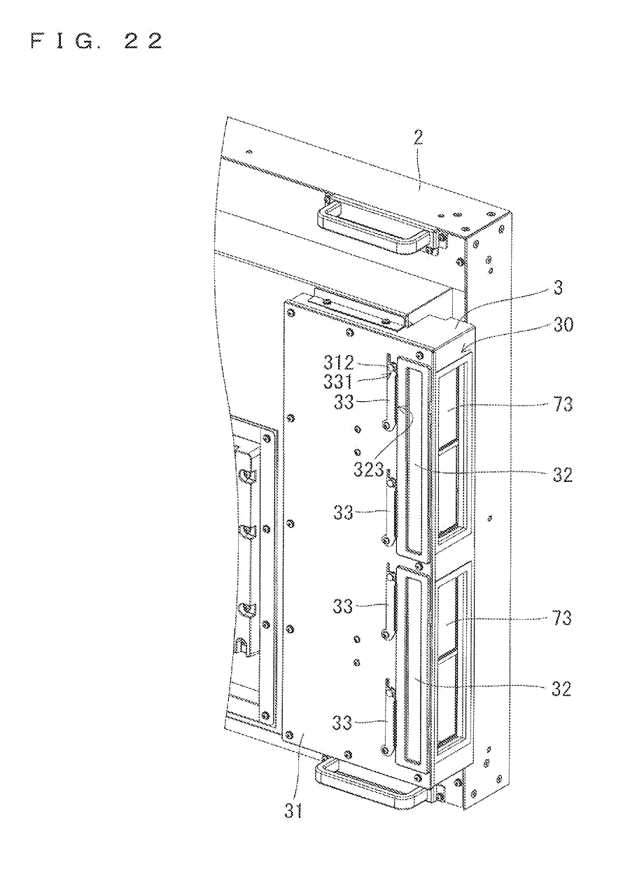

As shown in FIG. 21, in the support medium (322) of each of the inserting units (32), a pair of sword portions (323) (323) are formed in the upper side and the lower side. Each of the sword parts (323) contacts the back portion (31) of the inlet (31) when the inserting unit (32) is inserted to the corresponding insertion window (311). As shown in FIG. 20, in the back portion (31) of the inlet (3), a pair of arm parts (33) (33) are provided near each of the insertion windows (311) in the upper side and the lower side. This arm part (33) is provided so that it can pivot. For each of the arm portions (33), a sword portion (323) is provided. When the inserting unit (32) is inserted in the insertion window (311), each of the arm portion (33) overlaps the corresponding sword portion (323) from its outside by a predetermined angle. Thereby, as shown in FIG. 22, the sword part (323) is sandwiched between the arm portion (33) and the back portion (31) of the inlet (3), and thereby, the inserting unit (32) is fixed to the inlet (3) in a state inserted into the corresponding insertion window (311).

Further, in the back portion (31) of the inlet (3) and each of the arm portions (33), a locking structure for locking the arm portions (33) to the inlet (3) in the predetermined angle are provided. Here, this locking structure has a locking projection (312) provided in the back portion (31) of the inlet (3), and the locking groove portion (331) provided in the tip portion of the arm portion (33) which fits to the locking projection (312). Thereby, the fixing structure for fixing the inserting unit (32) to the inlet (3) in a state inserted to the insertion window (311) is provided by the sword portion (323), the arm portion (33) and the above-mentioned locking structure. In the tip portion of each of the arm portions (33), a manipulating portion (332) for user operation is provided.

According to the above-mentioned display device, by inserting the inserting unit (32) from the corresponding insertion window (311), the inlet side filter (73) is installed removable in the inlet (3). Each of the insertion windows (311) is formed in the back portion (31) of the inlet (3). Therefore, even when a duct is attached to the opening end (30) of the inlet (3), the inlet side filter (73) can be exchanged easily. Further, since the inlet side filter (73) can be exchanged from the back side of the display device, it is easy for users such as a serviceman to exchange the filter (73). This structure enabling the filter exchange from the back side of the display device is effective when the display device is built inside the other machine such as a vending machine.

Moreover, according to the above-mentioned display device, it is possible to design the height size of the fixing structure small. Therefore, the display device does not have to have a large thickness size even though the inlet side filter (73) can be exchanged from the back side.

In this example, the similar structure is adopted in the outlet (4) as in the inlet (3). However, the outlet side filter (74) provided in the outlet (4) consists only by the meshes.

### 4. Structure for Informing Clog Up of Filter

In the above-mentioned display device, in the inlet side filter (73), dust captured by this filter (73) accumulates. When the amount of accumulated dust increases, the inlet side filter (73) clogs up, and this hampers the inhalation of the air inside the cabinet. Therefore, when the inlet side filter (73) clogs up, it is required to exchange the filter, and if the exchanging time has elapsed, the temperature of the LCD panel (1) rises excessively, and this may cause an improper operation of the LCD panel (1).

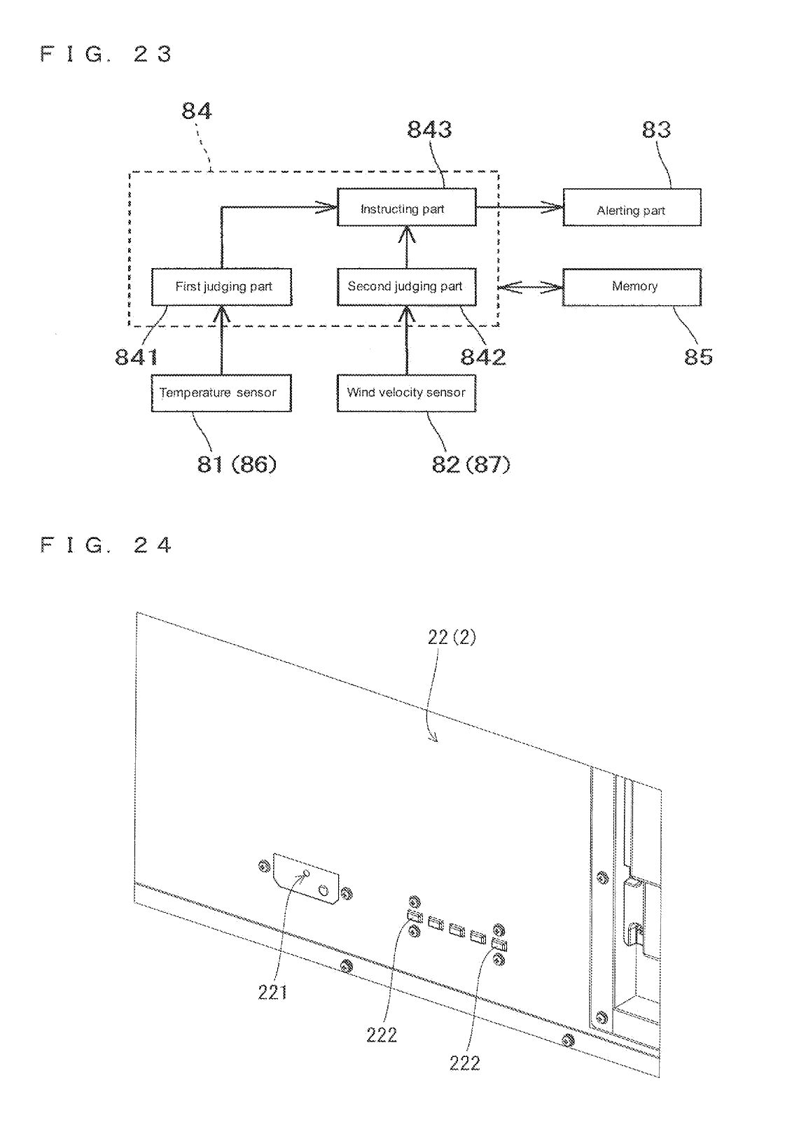

FIG. 23 is a block diagram showing the structure for informing the clog up of the filter. As shown in FIG. 23, the display device has a temperature sensor (81), a wind velocity sensor (82), an alerting part (83), a control part (84), and a memory (85). The temperature sensor (81) acquires temperature information which changes according to the temperature of the LCD panel (1). The wind velocity sensor (82) acquires wind velocity information which changes according to the speed of the air flowing inside the inlet (3). The alerting part (83) informs a clog up of the inlet side filter (73). The control part (84) controls the alerting executed by alerting part (83) based on the temperature information acquired by the temperature sensor (81) and the wind velocity information acquired by the wind velocity sensor (82). The memory (85) records a variety of information.

Here, as shown in FIG. 10, the temperature sensor (81) is arranged near the LCD panel (1) inside the inlet side channel (52). The wind velocity sensor (82) is installed between the inlet side filter (73) and the fan (71) inside the inlet (3). When the clog up arises in the inlet side filter (73), the temperature in the inlet side channel (52) rises and the velocity of the air emitted via the inlet side filter (73) becomes large compared with when clog up is not arising.

FIG. 24 is an enlarged view of the area G shown in FIG. 2. As shown in FIG. 24, in the back wall (22) of the cabinet (2), a penetration hole (221) which penetrates this back wall (22) from the inside and the outside is formed. The alerting part (83) is constituted by LED (Light Emitting Diode), and is provided in the back surface (12) side of the LCD panel (1) and inside the cabinet (2). The alerting part (83) faces toward the penetration hole (221). Thus, a user can recognize the light from the alerting part (83) through the penetration hole (221) from the back side of the cabinet (2). Further, as shown in FIG. 24, at the position near the penetration hole (221), plurality of adjusting buttons (222) (222) which adjust the image quality of the LCD panel (1) etc.

The control part (84) is arranged on the circuit board (11). As shown in FIG. 23, the control part (84) has a first judging part (841) and the second judging part (842). The first judging part (841) judges whether the temperature of the LCD panel (1) is higher than the predetermined temperature or not based on the temperature information acquired by the temperature sensor (81). The second judging part (842) judges whether the velocity of the air flowing inside the inlet (3) is larger than the predetermined speed or not based on the wind velocity information acquired by the wind velocity sensor (82).

When the display device is installed in a certain place in the indoors or the outdoors, and the display device is driven for the first time, temperature information and wind velocity information are acquired respectively by the temperature sensor (81) and the wind velocity sensor (82), and this information is recorded on the memory (85) as initial information. The above-mentioned predetermined temperature and predetermined speed are set up based on this initial information, and they are also recorded on the memory (85).

As shown in FIG. 23, the control part (84) further has an instructing part (843) which instructs the alerting part (83) to alert based on the judging result in the first and second judging parts (841) (842). When it is judged by the first judging part (841) that the temperature of the LCD panel (1) is higher than the predetermined temperature, or when it is judged by the second judging part (842) that the velocity of the air inside the inlet (3) is larger than the predetermined temperature, the instructing part (843) instructs the alerting part (83) to alert.

The alerting part (83) informs a clog up of the inlet side filter (73) by turning on or blinking LED, when receiving the instructions from the instructing part (843).

The above-mentioned display device can alert that the clog up in the inlet side filter (73) is occurring, and can inform that the exchanging time of the inlet side filter (73) has advent by the alerting part (83). The user can recognize the light from the alerting part (83) through the penetration hole (221) in the back side of the cabinet (2). Therefore, it can easily inform users, such as serviceman who often have chance to see the back side of the display devices, the clog up of the inlet side filter (73).

According to the above-mentioned display device, when the clog up arises in the inlet side filter (73), it can alert this situation immediately. Therefore, it can prevent from missing the exchange time of the inlet side filter (73), and prevent LCD panel (1) from the rising too much.

In the above-mentioned display device, as shown in FIG. 11, a temperature sensor (86) may be arranged near the LCD panel (1) inside the outlet side channel (53), and a wind velocity sensor (87) may be arranged between the outlet side filter (74) and the fan (72) inside the outlet (4). Then, based on temperature information acquired by the temperature sensor (86) and wind velocity information acquired by the wind velocity sensor (87), the clog up in the outlet side filter (74) may be informed to the alerting part (83).

Other implementations are contemplated. For example, in the above-mentioned display device, one of the inlet side channel (52) or the outlet side channel (53) may arranged on the upper surface side of the LCD panel (1), and the other channel may be arranged in the lower surface side of the panel (1). In other words, the first channel (51) may prolong along the vertical direction of the screen (10) of the panel (1). In the back wall (22) of the cabinet (2), the inlet (3) and the outlet (4) may be aligned in the vertical (up and down) direction.

In the above-mentioned display device, one of the fans (71) and (72) may be omitted. The control part (84) may control the alerting part (83) based on information from one of the temperature sensor (81) or the wind velocity sensor (82) only.

For another example, the above described structures may be applied not only to the display device having the LCD panel (1), but also to the display device having a plasma display panel, OLED display panel, or Electro-Luminescence panels, etc.

What is claimed is:

1. A display device comprising:
a display panel;
a cabinet which accommodates the display panel;
an aeration part provided inside the cabinet, the aeration part communicates between the outside and inside of the cabinet;
a fan which leads air to inside or to outside of the cabinet via the aeration part;
a filter arranged in the aeration part, and
an alerting part arranged in the back side of the display panel, and informs a clog up of the filter.

2. The display device of claim 1, further comprising:
a temperature sensor which acquires the temperature information which changes according to the temperature of the display panel, and
a control part which controls an operation of the alerting part based on the temperature information acquired by the temperature sensor.

3. The display device of claim 1, further comprising:
a wind velocity sensor which acquires wind velocity information which changes according to the speed of the air flowing through the aeration part, and
a control part which controls an operation of the alerting part based on the wind velocity information acquired the wind velocity sensor.

4. A display device comprising:
a display panel;
a cabinet which accommodates the display panel;
an aeration part arranged in the cabinet, which communicates the outside and inside of the cabinet, the aeration part faces its opening end to the lateral side and having an insertion window in the back side;
a fan which leads air to inside or to outside of the cabinet via the aeration part, and
a filter which is inserted from the insertion window and attached removable to the aeration part.

5. The display device of claim 4, further comprising:
a inserting unit to which the filter is attached, the insertion unit capable of being inserted from the insertion window, and
a fixing structure which fixes the inserting unit when the inserting unit is inserted in the insertion window, the fixing structure comprises:
a sword part contacting the back portion of the aeration part when the inserting unit is inserted in the insertion window;
an arm part which is fixed rotatable in the back side of the aeration part, and fixes the inserting unit by overlapping with the sword part, and
a locking structure arranged in the back side of the aeration part, the locking structure prevents the rotation of the arm part in a state the arm part and the sword parts are overlapped.

6. The display device of claim 4, wherein
the aeration parts are provided in two places of the cabinet, and
the air inhaled inside the cabinet from one of the aeration parts passes the front side of the display panel, and is exhausted outside of the cabinet from the other aeration part.

7. The display device of claim 4, further comprising:
a channel formed inside the cabinet, and prolonged from the aeration part reaching the surface of the display panel, and
a partition component which divides the channel into plurality of spaces, each of the spaces leads to the surface of the display panel from the aeration part, wherein
each of the fan is arranged corresponding to each of the spaces.

8. The display device of claim 7, further comprises a second aeration part provided inside the cabinet, the aeration part communicates the outside and the inside of the cabinet, wherein
the channel reaches the second aeration part via the front side of the screen the display panel, and
the partition component divides a portion of the channel into plurality of spaces which leads from the aeration part to the front side of the screen of the display panel.

9. A display device comprising:
a display panel;
a cabinet which accommodates the display panel;
an aeration part arranged in the cabinet, the aeration part communicates the outside and the inside of the cabinet;
a plurality of fans arranged in the aeration part;
a channel formed inside the cabinet, the channel being prolonged from the aeration part and reaches the surface of the display panel, and
a partition component which divides the channel into a plurality of spaces which leads to the surface of the display panel from the aeration part, wherein
each of the fans is arranged corresponding to each of the spaces in the channel.

10. The display device of claim 9, further comprises a second aeration part provided inside the cabinet, the aeration part communicates the outside and the inside of the cabinet, wherein
the channel reaches the second aeration part via the front side of the screen the display panel, and
the partition component divides a portion of the channel into plurality of spaces which leads from the aeration part to the front side of the screen of the display panel.
